(19) United States
(12) Patent Application Publication
(10) Pub. No.: US 2007/0042510 A1
(43) Pub. Date: Feb. 22, 2007

(54) In situ process monitoring and control

(75) Inventor: Woo Sik Yoo, Palo Alto, CA (US)

Correspondence Address: MACPHERSON KWOK CHEN & HEID LLP, 2033 GATEWAY PLACE, SUITE 400, SAN JOSE, CA, 95110, US

(73) Assignee: WaferMasters, Incorporated

(21) Appl. No.: 11/208,373

(22) Filed: Aug. 19, 2005

(51) Int. Cl. H01L 21/66

(52) U.S. Cl. 438/14; 257/E21.527

(57) ABSTRACT

Systems and methods for monitoring a semiconductor manufacturing process are provided. The method includes: performing a semiconductor manufacturing process step on a wafer; directing light having a known wavelength at the wafer; monitoring a predetermined spectral range of light transmitted through a selected region of the wafer to detect an optical characteristic of the selected region; and based on the detected optical characteristic of the selected region, adjusting a process condition of the semiconductor manufacturing process step.

### BACKGROUND

Semiconductor wafers, flat panel displays, and other similar semiconductor structures typically have numerous material layers deposited thereon during device fabrication. Semiconductor processing typically includes a multi-step sequence of photographic and chemical processing steps during which electronic circuits are gradually created on a substrate. During these steps, numerous layers are deposited sequentially and/or etched to form the device. The layers are patterned to form the desired connections or features.

In a typical process, a light-sensitive material, such as photoresist, is first deposited on a layer to be patterned, such as a dielectric or conductive layer. Light is then selectively directed onto the photoresist film through a photomask, or reticle, to form desired photoresist patterns on the base material. The photoresist is then developed to transfer the pattern of the mask to the photoresist layer. Next, portions of the photoresist are removed to expose corresponding underlying portions of the previous layer. Additional processing steps, such as the deposition of another layer, implantation, or etching, can be performed using the pattern defined by the photoresist.

Each step in a semiconductor manufacturing process requires the setting of various operational parameters for the process tool. During manufacturing, it can be difficult to assess the progress of the process being performed. In particular, it is difficult to determine when an etching, deposition, or diffusion process has reached its endpoint. One method is to cease the process step and remove the wafer from the process tool in order to inspect the state of the wafer. However, the delay and possible damage caused to the wafer by this removal and inspection process is undesirable.

Accordingly, there is a need for an improved method of providing in situ monitoring and process control for semiconductor process tools.

### SUMMARY

Systems and methods are provided for monitoring a semiconductor processing step on a wafer. The changing optical properties of the wafer are monitored during processing to determine the progress of the processing step.

In accordance with embodiments of the present invention, a method of monitoring a semiconductor manufacturing process is provided, comprising: performing a semiconductor manufacturing process step on a wafer; directing light having a known wavelength at the wafer; monitoring a predetermined spectral range of light transmitted through a selected region of the wafer to detect an optical characteristic of the selected region; and based on the detected optical characteristic of the selected region, adjusting a process condition of the semiconductor manufacturing process step.

In accordance with other embodiments of the present invention, a semiconductor manufacturing system is provided, comprising: a process chamber for performing a semiconductor manufacturing process step on a wafer; a light source for directing light having a known wavelength at the wafer; an imaging device for detecting light transmitted from the light source through a selected region of the wafer; an image processor for analyzing an image signal from the imaging device corresponding to a predetermined spectral range of light to detect an optical characteristic of the selected region; and a controller for adjusting a process condition of the semiconductor manufacturing process step based on the detected optical characteristic of the selected region.

In accordance with other embodiments of the present invention, a method of monitoring a semiconductor manufacturing process is provided, comprising: performing a semiconductor manufacturing process step on a wafer; directing light having a known wavelength at a bottom side of the wafer; monitoring a predetermined spectral range of light transmitted through a selected region of the wafer to detect a transmissivity of the selected region; and based on the detected change in the transmissivity of the selected region, adjusting a process condition of the semiconductor manufacturing process step.

Other features and aspects of the invention will become apparent from the following detailed description, taken in conjunction with the accompanying drawings which illustrate, by way of example, the features in accordance with embodiments of the invention. The summary is not intended to limit the scope of the invention, which is defined solely by the claims attached hereto.

### DESCRIPTION OF THE DRAWINGS

FIG. 1 shows a system for in situ monitoring and process control of a semiconductor manufacturing process, in accordance with embodiments of the present invention.

FIG. 2 is a flowchart illustrating a method of monitoring a semiconductor manufacturing process, in accordance with embodiments of the present invention.

FIGS. 3A-3B illustrate a method of monitoring a semiconductor manufacturing process being performed on a wafer, in accordance with embodiments of the present invention.

FIGS. 4A-4C illustrate a method of monitoring the size of a transmissive region of a wafer, in accordance with embodiments of the present invention.

### DETAILED DESCRIPTION

In the following description, reference is made to the accompanying drawings which illustrate several embodiments of the present invention. It is understood that other embodiments may be utilized and mechanical, compositional, structural, electrical, and operational changes may be made without departing from the spirit and scope of the present disclosure. The following detailed description is not to be taken in a limiting sense, and the scope of the embodiments of the present invention is defined only by the claims of the issued patent.

Some portions of the detailed description which follows are presented in terms of procedures, steps, logic blocks, processing, and other symbolic representations of operations on data bits that can be performed on computer memory. Each step may be performed by hardware, software, firmware, or combinations thereof.

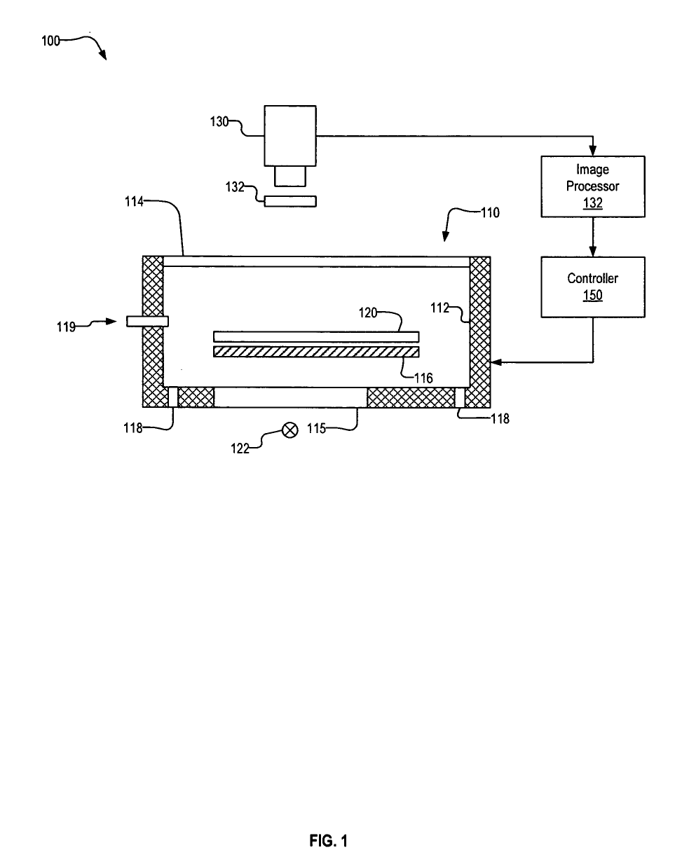

FIG. 1 shows a system 100 for in situ monitoring and process control of a semiconductor manufacturing process, in accordance with embodiments of the present invention. The system 100 may be used for a variety of semiconductor manufacturing process tools, including those used for deposition, oxidation, etching, diffusion, and any other processing steps that may be performed when manufacturing semiconductor devices (both inorganic and organic), MEMS (Micro-Electro-Mechanical Systems) devices, FPD (flat panel display) devices, and the like. It will be understood that the components and functionality of the system 100 may vary, depending on the application.

In the illustrated embodiment, the system 100 includes a process chamber 110 having a housing 112 with an upper window 114 and a lower window 115. A plate or stage 116 is provided for supporting a substrate 120 within the chamber 110. Depending on the type of process tool, one or more inlet and outlet ports may be provided in the housing, including one or more exhaust ports 118, for expelling gases or vapor from the chamber 110, and one or more intake ports 119 for providing process gases to the interior of the chamber 110. A controller 150 is provided for controlling the operation of the process chamber 110. The types of operational parameters controlled by the controller 150 may vary depending on the application, but may include chamber temperature, light source, RF power, microwave power, gas flow, pressure, processing time, and the like.

In accordance with embodiments of the present invention, the system 100 includes a light source 122, an imaging device 130, and an image processor 132 for providing in situ process monitoring and control. This monitoring method utilizes the optical characteristics of different materials forming the various layers of a semiconductor device.

In particular, different materials have different optical properties based on the energy bandgap of the material. The bandgap is the energy difference between the top of the valence band and the bottom of the conduction band in insulators and semiconductors. The bandgap is the property that determines at which wavelength the material emits light or absorbs it. The material is transparent to electromagnetic energy having a wavelength below the emission wavelength of the material, and is opaque to energy having a wavelength above the emission wavelength.

For example, silicon is transparent to electromagnetic energy in the infrared (IR) portion of the spectrum but is opaque to photons in the visible portion of the spectrum. A compound semiconductor such as a III-V compound, gallium arsenide (GaAs), also forms a lattice with covalent bonding, also making GaAs transparent to infrared light, which is unable to break the electron bonds, and opaque to visible light, which can break bonds. Similarly, aluminum oxide (Al₂O₃) is transparent from around 180 nm in the ultraviolet (UV) spectral range to around 6 μm in the IR spectral range. Si₃N₄ and SiC are transparent to X-rays of particular wavelengths. The exact transmittance properties of a material are a function of the material's thickness and purity. Germanium also has a broad transparency band (up to 12 μm), but becomes opaque at elevated temperatures, depending on the thickness of the layer. Other examples of materials exhibiting transparency to certain wavelengths of light including gallium nitride (GaN), silica (SiO₂), silicon nitride (SiN), quartz, silicon oxynitride (SiON), zinc selenide, zinc sulfide, spinel (MgAl₂O₄), and aluminum oxynitride (AlON).

Due to the varying optical characteristics (in particular, light transmissivity) of different materials used in semiconductor processing, it is possible to monitor the optical characteristics of a particular region in a substrate undergoing processing in order to determine the state of the wafer during processing.

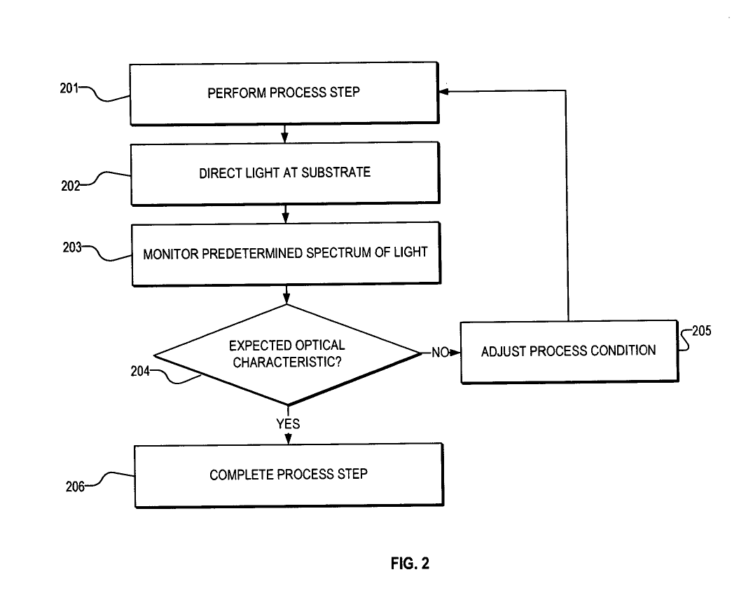

FIG. 2 is a flowchart illustrating a method of monitoring a semiconductor manufacturing process, in accordance with embodiments of the present invention. In step 201, a semiconductor manufacturing process step is performed using the process chamber 110. In step 202, light having a known wavelength is directed at the substrate 120 contained in the process chamber 110. In step 203, a predetermined spectral range of light transmitted through a selected region of the substrate 120 is monitored. In step 204, based on the monitored light, an optical characteristic of the selected region is compared to an expected optical characteristic. If the optical characteristic is not as expected, a process condition is adjusted in step 205 and the process step continues. If the optical characteristic is as expected, the process step is completed in step 206.

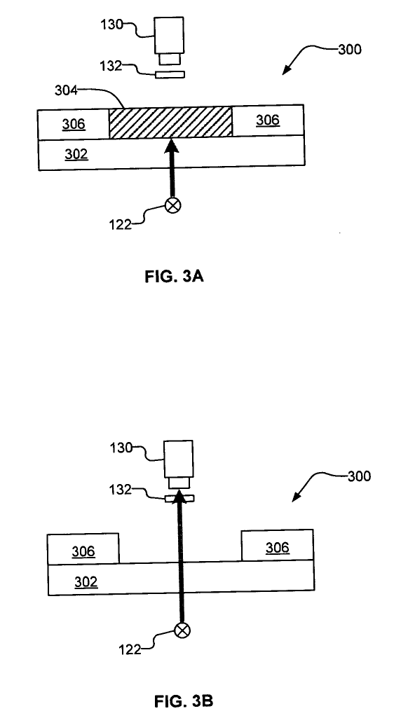

FIGS. 3A-3B illustrate a simple example of in situ endpoint detection of a semiconductor manufacturing process being performed on a wafer 300. FIG. 3A shows the state of the wafer 300 (a portion of which is shown in FIGS. 3A-3B) at the beginning of the process step. The wafer 300 may include multiple layers of different types of materials. However, in the illustrated example, the substrate comprises a silicon substrate 302, having a patterned metal layer 304 (e.g., an aluminum layer) surrounded by a dielectric layer 306. In this example, the process step being performed comprises a plasma etching process to remove the metal layer 304.

The light source 122 directs light at the bottom of the wafer 300. The light source 122 may be configured to direct a broadband spectrum of light, or may be configured to direct a particular wavelength or narrow spectral range of light at the wafer 300. A waveguide, such as an optical fiber, may be provided for precisely directing the light to a desired region of the wafer 300. In this example, the light source 122 directs light in the IR spectral range at the bottom of the substrate 302 in a region corresponding to the metal layer 304.

An imaging device 130 is provided on the opposite side of the wafer 300 to detect the light from the light source 122 transmitted through the wafer 300. The imaging device 130 may comprise, e.g., a CCD camera. A filter 132 may be provided so that only IR light is detected by the imaging device 130, and that light from other sources (such as, e.g., energized plasma within the chamber 110) will be filtered out of the signal. Because the metal layer 304 is opaque to IR light, the IR light from the light source 122 cannot pass through the wafer 300. Therefore, as long as the metal layer 304 is present in the region being monitored by the imaging device 130, the IR light from the light source 122 will not be detected.

FIG. 3B shows the state of the wafer 300 after the metal layer 304 has been removed. Because silicon is transparent to IR light, the light from the light source 122 can pass through the silicon substrate 302. Once the metal layer 304 has been removed, the IR light will pass through the wafer 300 and be detected by the imaging device 130. Thus, the imaging device 130 can serve as an endpoint detector for the etching process. This can be accomplished using the image processor 132 and controller 150, shown in FIG. 1. The image processor 132 processes the image signal generated by the imaging device 130. When the image processor 132 determines that a sufficient amount of IR light corresponding to the removal of the metal layer 304 has been detected by the imaging device 130, the image processor 132 will transmit an endpoint signal to the controller 150. When the controller 150 receives the endpoint signal, the controller 150 terminates the etching process.

The monitoring and detection of the IR light from the light source 122 may occur at various times during the manufacturing process. In some embodiments, the manufacturing process may temporarily cease while the imaging device 130 attempts to detect the light from the light source 122. In other embodiments, the imaging device 130 may continuously monitor the wafer for the detection of the light from the light source 122 as the manufacturing process proceeds. An alignment mechanism may be provided for ensuring that the imaging device 130 is aligned with the light source 122, and that both the imaging device 130 and the light source 122 are positioned to monitor the desired region of the wafer.

In accordance with other embodiments, the system 100 may be used for process control. For example, the controller 150 may be provided with expected optical characteristic states for various points during the manufacturing process. If the imaging device 130 does not detect the expected optical characteristic at any point during the process, the controller 150 may adjust a process condition of the chamber 110. In the example above, if the IR light has not been detected within a predetermined amount of time after initiation of the etching process, the controller 150 may adjust one or more of the operational parameters of the chamber 110 in order to increase the speed of metal removal. In other cases, if the IR light is detected earlier than expected for multiple etching processes, one or more operational parameters of the chamber 110 may be adjusted for subsequent wafers in order to decrease etching speed.

In accordance with the embodiment described above, the image processor 132 monitors the signal from the imaging device 130 for detection of an expected wavelength of light. In other embodiments, the image processor 132 may process the signal in other ways. For example, the image processor 132 may analyze the signal to determine whether an expected intensity of light (either broadband or of limited spectral range) has been detected. Thus, the image processor 132 may be able to monitor the progress of the deposition, removal, or diffusion of a particular layer, based on the changing optical characteristics of the wafer as the deposition, removal, or diffusion proceeds. The observed change in the optical characteristics can be compared to expected optical characteristics in order to provide improved process control.

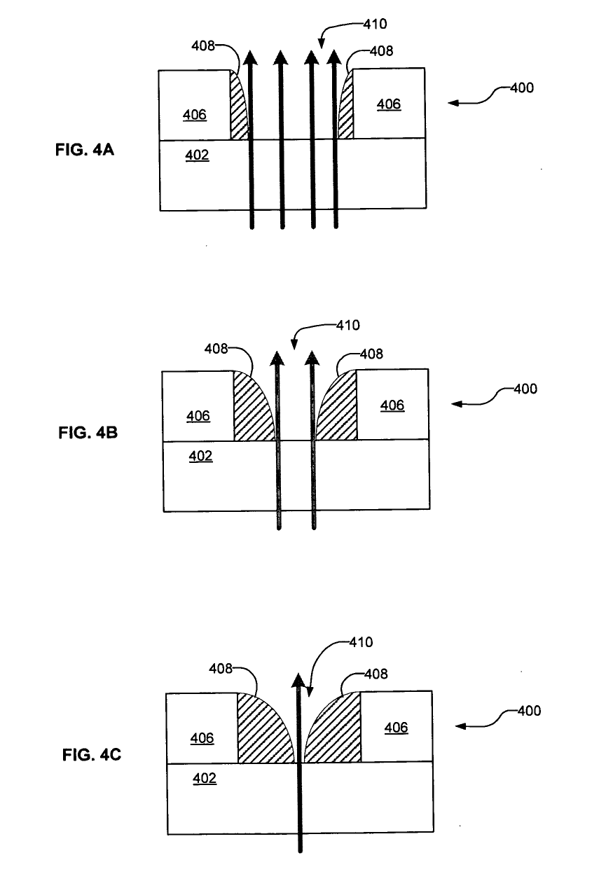

In yet other embodiments, the image processor 132 may analyze the signal to determine whether an expected image has been detected. FIGS. 4A-4C illustrate an embodiment in which the size of the transmissive region of a wafer 400 is monitored. The wafer 400 includes an optically transparent substrate 402 on which a deposition process is being performed in order to form opaque sidewalls 408. Thus, the imaging device 130 is able to detect light passing through the substrate 402 between the sidewalls 408. As the sidewalls 408 grow, the size of the transmissive region 408 decreases, as shown in FIGS. 4A-4C.

In yet other embodiments, other types of optical characteristics may be monitored. For example, interference patterns produced by the transmission of light through various structures having different optical characteristics may be analyzed. Each layer in the semiconductor wafer may be treated as a filter for a particular type of light. Therefore, the effect of the combination and arrangement of materials on light from the light source may be analyzed in order to determine the progress of a semiconductor processing step.

While the invention has been described in terms of particular embodiments and illustrative figures, those of ordinary skill in the art will recognize that the invention is not limited to the embodiments or figures described. For example, the embodiments described above provide examples for monitoring and process control of deposition and etching processes. In other embodiments, the semiconductor manufacturing process being monitored may vary. For example, the changing optical properties of the wafer during diffusion or oxidation steps may be monitored in order to provide endpoint detection and/or process control.

In addition, in the above-described embodiments, a single imaging device and a single light source are provided. In other embodiments, the multiple imaging devices (such as a CCD array) and/or multiple light sources may be used to monitor changing optical characteristics of different locations on the processed wafer.

In the embodiment illustrated in FIG. 1, the light source 122 and imaging device 130 are positioned outside of the process chamber 110, and windows 114, 115 are provided to allow the light to enter and exit the process chamber 110. Similarly, a window or aperture may be provided in the wafer stage 116 to allow the light to reach the bottom of the wafer. In other embodiments, either or both the light source 122 and the imaging device 130 may be provided within the process chamber 110. In this case, the light source 122 and/or the imaging device 130 should be capable of operating while subjected to the conditions within the chamber.

In various embodiments, the region of the wafer being monitored may vary in size and location. In some embodiments, the region corresponds to a very small region of the wafer, such as, e.g., a 0.1 μm spot on the surface of the wafer. In other embodiments, the region may correspond to a very large region of the wafer, such as a 15 mm spot covering an entire die on the wafer or the entire sample area (e.g., the wafer or glass plate). In this case, the transmissivity being monitored corresponds to the overall transmissivity of the entire die region, rather than the transmissivity of a single device or layer. In yet other embodiments, the region being monitored may be a test region designed to provide a predetermined optical characteristic at one or more points during the manufacturing process.

The program logic described indicates certain events occurring in a certain order. Those of ordinary skill in the art will recognize that the ordering of certain programming steps or program flow may be modified without affecting the overall operation performed by the preferred embodiment logic, and such modifications are in accordance with the various embodiments of the invention. Additionally, certain of the steps may be performed concurrently in a parallel process when possible, as well as performed sequentially as described above.

Therefore, it should be understood that the invention can be practiced with modification and alteration within the spirit and scope of the appended claims. The description is not intended to be exhaustive or to limit the invention to the precise form disclosed. It should be understood that the invention can be practiced with modification and alteration and that the invention be limited only by the claims and the equivalents thereof.

What is claimed is:

1. A method of monitoring a semiconductor manufacturing process, comprising:
performing a semiconductor manufacturing process step on a wafer;
directing light having a known wavelength at the wafer;
monitoring a predetermined spectral range of light transmitted through a selected region of the wafer to detect an optical characteristic of the selected region; and
based on the detected optical characteristic of the selected region, adjusting a process condition of the semiconductor manufacturing process step.

2. The method of claim 1, wherein:
said monitoring the predetermined spectral range of light comprises detecting a cessation of transmission of the predetermined spectral range of light or detecting an onset of transmission of the predetermined spectral range of light.

3. The method of claim 2, wherein:
said adjusting the process condition comprises ceasing the process step in response to either detecting the cessation of transmission of the predetermined spectral range of light or detecting the onset of transmission of the predetermined spectral range of light.

4. The method of claim 1, wherein:
said adjusting the process condition of the semiconductor manufacturing process step comprises adjusting the process condition of the semiconductor manufacturing process step based on a comparison of a detected rate of change of the detected optical characteristic to an expected rate of change of the optical characteristic.

5. The method of claim 1, wherein:
said monitoring the predetermined spectral range of light transmitted through the selected region of the wafer comprises monitoring a size of the predetermined spectral range of light transmitted through the selected region of the wafer.

6. The method of claim 1, wherein:
said directing light having the known wavelength comprises directing wide spectrum light at the wafer.

7. The method of claim 1, wherein:
said directing light having the known wavelength comprises directing a single wavelength of light at the wafer.

8. The method of claim 1, wherein:
said monitoring the predetermined spectral range of light comprises monitoring the predetermined spectral range of light using a camera and a filter selective for the predetermined spectral range of light.

9. A semiconductor manufacturing system, comprising:
a process chamber for performing a semiconductor manufacturing process step on a wafer;
a light source for directing light having a known wavelength at the wafer;
an imaging device for detecting light transmitted from the light source through a selected region of the wafer;
an image processor for analyzing an image signal from the imaging device corresponding to a predetermined spectral range of light to detect an optical characteristic of the selected region; and
a controller for adjusting a process condition of the semiconductor manufacturing process step based on the detected optical characteristic of the selected region.

10. The system of claim 9, wherein:
said image processor is configured to detect a cessation of transmission of the predetermined spectral range of light or to detect an onset of transmission of the predetermined spectral range of light.

11. The system of claim 10, wherein:
said controller is configured to cease the process step in response to either the detection of the cessation of transmission of the predetermined spectral range of light or the detection of the onset of transmission of the predetermined spectral range of light.

12. The system of claim 9, wherein:
said controller is configured to adjust the process condition of the semiconductor manufacturing process step based on a comparison of a detected rate of change of the detected optical characteristic to an expected rate of change of the optical characteristic.

13. The system of claim 9, wherein:
said image processor is configured to monitor a size of the predetermined spectral range of light transmitted through the selected region of the wafer.

14. The system of claim 9, wherein:
said light source is configured to direct a wide spectrum light at the wafer.

15. The system of claim 9, wherein:
said light source is configured to direct a single wavelength of light at the wafer.

16. The system of claim 9, wherein:
further comprising a filter selective for the predetermined spectral range of light, said filter being positioned to filter light entering the imaging device.

17. A method of monitoring a semiconductor manufacturing process, comprising:
performing a semiconductor manufacturing process step on a wafer;
directing light having a known wavelength at a bottom side of the wafer;
monitoring a predetermined spectral range of light transmitted through a selected region of the wafer to detect a transmissivity of the selected region; and
based on the detected change in the transmissivity of the selected region, adjusting a process condition of the semiconductor manufacturing process step.

18. The method of claim 17, wherein:
said monitoring the predetermined spectral range of light comprises detecting a cessation of transmission of the predetermined spectral range of light or detecting an onset of transmission of the predetermined spectral range of light.

19. The method of claim 18, wherein:
said adjusting the process condition comprises ceasing the process step in response to either detecting the cessation of transmission of the predetermined spectral range of light or detecting the onset of transmission of the predetermined spectral range of light.

20. The method of claim 1, wherein:
said adjusting the process condition of the semiconductor manufacturing process step comprises adjusting the process condition of the semiconductor manufacturing process step based on a comparison of a detected rate of change of the transmissivity of the selected region to an expected rate of change of the transmissivity of the selected region.
